(19) United States
(12) Patent Application Publication
(10) Pub. No.: US 2025/0379113 A1
(43) Pub. Date: Dec. 11, 2025

(54) SEMICONDUCTOR PACKAGE AND MANUFACTURING METHOD THEREOF

(71) Applicant: Samsung Electronics Co., Ltd., Suwon-si (KR)

(72) Inventors: Youngmin Yun, Suwon-si (KR); Ji-Yong Park, Suwon-si (KR)

(21) Appl. No.: 18/924,507

(22) Filed: Oct. 23, 2024

(30) Foreign Application Priority Data
Jun. 7, 2024 (KR) 10-2024-0074306

(51) Int. Cl. H01L 23/367; H01L 23/00; H01L 23/498

(52) U.S. Cl. CPC H01L 23/3675; H01L 23/49827; H01L 24/32; H01L 24/33; H01L 24/16; H01L 24/73; H01L 2224/16227; H01L 2224/26175; H01L 2224/32225; H01L 2224/33181; H01L 2224/73204

(57) ABSTRACT

A semiconductor package may include a substrate including a substrate base and a plurality of dummy pattern structures penetrating the substrate base in a vertical direction, a semiconductor die on the substrate, and a heat dissipation structure on the substrate and surrounding at least a portion of the semiconductor die, where the heat dissipation structure is connected to the plurality of dummy pattern structures.

### CROSS-REFERENCE TO RELATED APPLICATION

This application claims priority to and the benefit of Korean Patent Application No. 10-2024-0074306, filed in the Korean Intellectual Property Office on Jun. 7, 2024, the entire disclosure of which is incorporated herein by reference.

### FIELD

The present disclosure relates to a semiconductor package and a manufacturing method thereof.

### BACKGROUND

In accordance with demand in the semiconductor industry, semiconductor dies (semiconductor chips) are becoming lighter, thinner, smaller, faster, and more functional. As semiconductor dies become lighter, thinner, smaller, faster, and more functional, the power per unit volume consumed by the semiconductor die increases, which increases the heat generated from the semiconductor die. If the heat generated in the semiconductor die is not released to the outside, the heat stays in the semiconductor package including the semiconductor die, and a thermal stress difference occurs within the semiconductor package structure, which may cause warpage in the semiconductor package. In addition, if the heat generated by the semiconductor die cannot be released to the outside, the temperature of the semiconductor package increases, and as the temperature increases, it may affect the operating speed of the semiconductor die, which can worsen product reliability.

To solve these problems, heat slugs made of metal materials with high thermal conductivity are being used in semiconductor packages. The heat slug may contact the upper or side surfaces of the semiconductor die, and may be disposed to cover the semiconductor die on the substrate, and the features of shape, arrangement, and structure of the heat slug allow heat generated in the semiconductor die to dissipate to the top of the semiconductor package. However, since heat may accumulate at the bottom of the semiconductor die or within the substrate within the semiconductor package, there is a limit to dissipating heat under the semiconductor die or within the substrate using only the heat slug.

### SUMMARY

Some embodiments of the present disclosure provide a semiconductor package including a substrate and a semiconductor die on the substrate, where the substrate may include dummy pattern structures, and the semiconductor die may be covered by a heat dissipation structure disposed on the substrate, and the semiconductor die, the dummy pattern structures, and the heat dissipation structure are thermally interconnected.

Some embodiments of the present disclosure provide a semiconductor package including a substrate and a semiconductor die on the substrate, where the substrate may include dummy pattern structures, a dam structure may be disposed on the substrate, the semiconductor die may be covered by a heat dissipation structure disposed on the dam structure, and the semiconductor die, the dummy pattern structures, the dam structure, and the heat dissipation structure are thermally interconnected.

A semiconductor package may include a substrate including a substrate base and a plurality of dummy pattern structures penetrating the substrate base in a vertical direction, a semiconductor die on the substrate, and a heat dissipation structure on the substrate and surrounding at least a portion of the semiconductor die, where the heat dissipation structure is connected to the plurality of dummy pattern structures.

A semiconductor package may include a substrate including a substrate base and a plurality of dummy pattern structures penetrating the substrate base in a vertical direction, a semiconductor die on the substrate, a dam structure on the substrate and surrounding at least a portion of the semiconductor die, where the dam structure is connected to the plurality of dummy pattern structures, and a heat dissipation structure on the dam structure and surrounding at least a portion of the semiconductor die, where the heat dissipation structure is connected to the dam structure.

A semiconductor package may include a substrate including a substrate base, a plurality of dummy pattern structures penetrating the substrate base in a vertical direction, and a plurality of connection members on a lower surface of the substrate base, a semiconductor die on the substrate, a dam structure on the substrate and surrounding at least a portion of the semiconductor die, where the dam structure is connected to the plurality of dummy pattern structures, a molding material on the substrate and within the dam structure, the molding material configured to cover a portion of the semiconductor die, and a heat dissipation structure on the dam structure, on the molding material, and surrounding at least a portion of the semiconductor die, where the heat dissipation structure is connected to the dam structure.

The heat generated from the semiconductor die and the heat accumulated within the semiconductor package may be dissipated through the upper surface, side surfaces, and lower surface of the semiconductor package. Accordingly, the semiconductor package has heat dissipation paths in six directions of an upper surface direction, side surface directions, and a lower surface direction of the semiconductor package, and may improve thermal characteristics of the semiconductor package by maximally securing the heat dissipation area.

The semiconductor package may include dummy pattern structures, a dam structure, and a heat dissipation structure having various structures, shapes, and arrangements within the semiconductor package, and may improve thermal characteristics of the semiconductor package.

### BRIEF DESCRIPTION OF THE DRAWINGS

FIG. 1 is a cross-sectional view showing a semiconductor package according to some embodiments.

FIG. 2 is a top plan view showing the substrate of FIG. 1.

FIG. 3 is a top plan view showing the semiconductor package of FIG. 1 excluding an adhesive member and a heat dissipation structure.

FIG. 4 is a cross-sectional view showing a semiconductor package according to some embodiments.

FIG. 5 is a cross-sectional view showing a semiconductor package according to some embodiments.

FIG. 6 is a cross-sectional view showing a semiconductor package according to some embodiments.

FIG. 7 is a cross-sectional view showing a semiconductor package according to some embodiments.

FIG. 8 is a cross-sectional view showing a semiconductor package according to some embodiments.

FIG. 9 is a cross-sectional view showing a semiconductor package according to some embodiments

FIG. 10 is a cross-sectional view showing a semiconductor package according to some embodiments.

FIG. 11 to FIG. 16 are cross-sectional views for explaining a method of manufacturing the semiconductor package of FIG. 1.

### DETAILED DESCRIPTION

The present disclosure will be described more fully hereinafter with reference to the accompanying drawings, in which example embodiments of the disclosure are shown. As those skilled in the art would realize, the described embodiments may be modified or combined in various different ways, all without departing from the spirit or scope of the present disclosure.

The drawings and description are to be regarded as illustrative in nature and not restrictive. Like reference numerals designate like elements throughout the specification.

Further, in the drawings, the size and thickness of each element may be arbitrarily illustrated for ease of description, and the present disclosure is not necessarily limited to those illustrated in the drawings.

Throughout this specification and the claims that follow, when it is described that an element is “coupled or connected” to another element, the element may be “directly coupled or connected” to the other element or “indirectly coupled or connected” to the other element through a third element. In addition, unless explicitly described to the contrary, the word “comprise” and variations such as “comprises” or “comprising” will be understood to imply the inclusion of stated elements but not the exclusion of any other elements.

It will be understood that when an element such as a layer, film, region, area, or substrate is referred to as being “on” another element, it can be directly on the other element or intervening elements may also be present. In contrast, when an element is referred to as being “directly on” another element, there are no intervening elements present. Further, in the specification, the word “on” or “above” may mean positioned on or below the object portion, and does not necessarily mean positioned on the upper side of the object portion based on a gravitational direction.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

Hereinafter, a semiconductor package 100 according to example embodiments and a manufacturing method thereof will be described in detail with reference to the drawings.

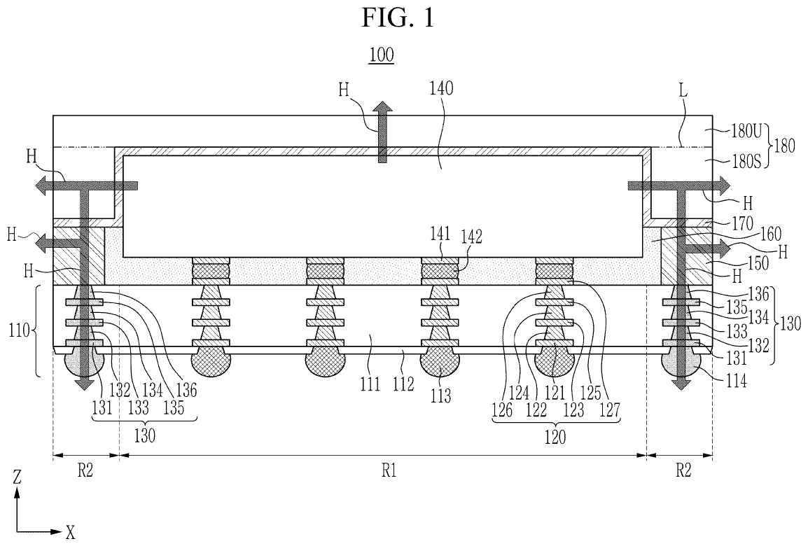

FIG. 1 is a cross-sectional view showing the semiconductor package 100 according to some embodiments.

Referring to FIG. 1, the semiconductor package 100 may include a substrate 110, a semiconductor die 140, a dam or dam structure 150, a molding material or molding member 160, an adhesive member 170, and a heat dissipation structure 180. In some embodiments, the semiconductor package 100 may be manufactured based on fan-out wafer level package (FOWLP) or fan-out panel level package (FOPLP) technology.

The substrate 110 may include a substrate base 111, an insulation member 112, first connection members 113, second connection members 114, wiring pattern structures 120, and dummy pattern structures 130. In some embodiments, the substrate 110 may include a printed circuit board (PCB). In some embodiments, the substrate 110 may include an embedded trace substrate (ETS) having a coreless form in which the core layer is removed.

The substrate base 111 may include the wiring pattern structures 120 excluding bonding pads 127, and the dummy pattern structures 130. The substrate base 111 may protect and insulate the wiring pattern structures 120 excluding the bonding pads 127, and the dummy pattern structures 130. The bonding pads 127, the dam structure 150, and the molding material 160 may be disposed on an upper surface of the substrate base 111. The insulation member 112, the first connection members 113, and the second connection members 114 may be disposed on a lower surface of the substrate base 111. The substrate base 111 may include a central region (first region) R1 and an edge region (second region) R2 around or surrounding the central region R1 defined by dividing the plane of the substrate base 111.

The substrate base 111 may include a dielectric. In some embodiments, the dielectric may include a thermosetting resin such as an epoxy resin, a thermoplastic resin such as polyimide, or a material in which the above-mentioned resin is mixed with an inorganic filler. In some embodiments, the dielectric may include a resin impregnated into a core material such as, glass fiber (or glass cloth or glass fabric) or a material in which the above-mentioned resin is mixed with an inorganic filler. In some embodiments, the dielectric may include prepreg, Ajinomoto Build-up Film (ABF), FR-4, or bismaleimide triazine (BT). In some embodiments, the dielectric may include a photoimageable dielectric (PID).

The insulation member 112 may be disposed on the lower surface of the substrate base 111. The insulation member 112 may include through openings for soldering. Each of the first connection members 113 or each of the second connection members 114 may be disposed within each through opening of the insulation member 112. The insulation member 112 may surround a portion of a side surface of each of the first connection members 113, and a portion of a side surface of each of the second connection members 114. The insulation member 112 may prevent the first connection members 113 and the second connection members 114 from being short-circuited. In some embodiments, the insulation member 112 may include a solder resist.

The first connection members 113 may be disposed on the lower surface of the substrate base 111. The first connection members 113 may be disposed below or at the central region R1 of the substrate base 111. Each of the first connection members 113 may be disposed within respective ones of the through openings of the insulation member 112. Each of the first connection members 113 may be disposed below each of first wiring lines 121. Each of the first connection members 113 may electrically connect each of the first wiring lines 121 to an external device. Each of the first connection members 113 may route signals or electric power transferred to the semiconductor die 140, or may route signals or electric power transferred from the semiconductor die 140. In some embodiments, the first connection members 113 may include solder balls or bumps.

The second connection members 114 may be disposed on the lower surface of the substrate base 111. The second connection members 114 may be disposed below or at the edge region R2 of the substrate base 111. Each of the second connection members 114 may be disposed within respective ones of the through openings of the insulation member 112. Each of the second connection members 114 may be disposed below each of first dummy lines 131. Each of the second connection members 114 may physically connect each of the first dummy lines 131 to an external device. Each of the second connection members 114 may be a dummy connection member, and may not route signals or electric power. In some embodiments, the second connection members 114 may include solder balls or bumps.

The wiring pattern structures 120 may be disposed in or at the central region R1 of the substrate base 111. The wiring pattern structures 120 may penetrate or extend through the substrate base 111 in a Z direction (vertical direction). Each of the wiring pattern structures 120 may include the first wiring line 121, a first wiring via 122, a second wiring line 123, a second wiring via 124, a third wiring line 125, a third wiring via 126, and the bonding pad 127. The first wiring line 121, the first wiring via 122, the second wiring line 123, the second wiring via 124, the third wiring line 125, and the third wiring via 126 may be disposed within the substrate base 111. The bonding pad 127 may be disposed on the upper surface of the substrate base 111. The wiring pattern structures 120 may be wiring via stacks.

The first wiring line 121, the first wiring via 122, the second wiring line 123, the second wiring via 124, the third wiring line 125, the third wiring via 126, and the bonding pad 127 may be sequentially disposed from the bottom, and may be electrically interconnected. As illustrated in FIG. 1, the wiring pattern structure 120 includes three layers of vias, however, in other embodiments, the wiring pattern structure 120 including smaller or greater number of wire layers and vias may be included in the scope of the present disclosure. In some embodiments, the first wiring line 121, the first wiring via 122, the second wiring line 123, the second wiring via 124, the third wiring line 125, the third wiring via 126, and the bonding pad 127 may include at least one of copper, aluminum, silver, tin, gold, nickel, lead, titanium, and an alloy thereof, respectively.

The dummy pattern structures 130 may be disposed in or at the edge region R2 of the substrate base 111. The dummy pattern structures 130 may penetrate or extend through the substrate base 111 in the Z direction (vertical direction). Each of the dummy pattern structures 130 may be disposed between the dam structure 150 and each of the second connection members 114. Each of the dummy pattern structures 130 may thermally connect the dam structure 150 to each of the second connection members 114. Each of the dummy pattern structures 130 may include the first dummy line 131, a first dummy via 132, a second dummy line 133, a second dummy via 134, a third dummy line 135, and a third dummy via 136. The first dummy line 131, the first dummy via 132, the second dummy line 133, the second dummy via 134, the third dummy line 135, and the third dummy via 136 may be disposed within the substrate base 111. The dummy pattern structures 130 may be dummy via stacks. Each of the dummy pattern structures 130 is a dummy member, and does not route signals or electric power.

The first dummy line 131, the first dummy via 132, the second dummy line 133, the second dummy via 134, the third dummy line 135, and the third dummy via 136 may be sequentially disposed from the bottom, and may be thermally interconnected. As illustrated in FIG. 1, the dummy pattern structure 130 includes three layers of vias, however, in other embodiments, the dummy pattern structure 130 including smaller or greater number of wire layers and vias may be included in the scope of the present disclosure. In some embodiments, the first dummy line 131, the first dummy via 132, the second dummy line 133, the second dummy via 134, the third dummy line 135, and the third dummy via 136 may include at least one of copper, aluminum, silver, tin, gold, nickel, lead, titanium, and an alloy thereof, respectively.

A portion of a heat generated from the semiconductor die 140 may be transferred to the dummy pattern structures 130 through the heat dissipation structure 180 and the dam structure 150. The dummy pattern structures 130 may dissipate the transferred heat in a downward direction (−Z direction) of the semiconductor package 100 through the second connection members 114. In addition, the dummy pattern structures 130 may dissipate a portion of a heat accumulated within the semiconductor package 100 in the downward direction (−Z direction) of the semiconductor package 100 through the second connection members 114.

The semiconductor die 140 may be disposed on the substrate 110. The semiconductor die 140 may be in a plural quantity. In some embodiments, the semiconductor die 140 may include a 3DIC (3 Dimensional Integrated Circuit). In some embodiments, the semiconductor die 140 may include a logic die or memory die. In some embodiments, the semiconductor die 140 may include system-on-chip (SoC), application processor (AP), or high bandwidth memory (HBM).

The semiconductor die 140 may include connection pads 141. Each of the connection pads 141 may be disposed between each of the wirings of the semiconductor die 140 and each of third connection members 142. Each of the connection pads 141 may electrically connect each of the wirings of the semiconductor die 140 to each of the third connection members 142. In some embodiments, the connection pads 141 may include at least one of copper, aluminum, silver, tin, gold, nickel, lead, titanium, and an alloy thereof.

Each of the third connection members 142 may be disposed between each of the connection pads 141 and each of the bonding pads 127. Each of the third connection members 142 may electrically connect each of the connection pads 141 to each of the bonding pads 127. In some embodiments, the third connection members 142 may include micro-bumps or solder balls. In some embodiments, the third connection members 142 may include at least one of tin, silver, lead, nickel, copper, and an alloy thereof.

The dam structure 150 may be disposed on an upper surface of the substrate 110. The dam structure 150 may be disposed to at least partially surround the semiconductor die 140. The dam structure 150 may be disposed between the dummy pattern structures 130 and the heat dissipation structure 180. The dam structure 150 may thermally connect the heat dissipation structure 180 to the dummy pattern structures 130. The dam structure 150 may be spaced apart from the semiconductor die 140 (e.g., horizontally spaced apart). An inner side surface of the dam structure 150 may contact the molding material 160, and an exterior side of the dam structure 150 may be exposed to the outside. An upper surface of the dam structure 150 may have the same (vertical) level as a (vertical) level of an upper surface of the molding material 160 (e.g., coplanar). A (vertical) level of the upper surface of the dam structure 150 may be located between a (vertical) level of a lower surface of the semiconductor die 140 and a (vertical) level of an upper surface of the semiconductor die 140. In some embodiments, the dam structure 150 may include a conductive material having a high thermal conductivity.

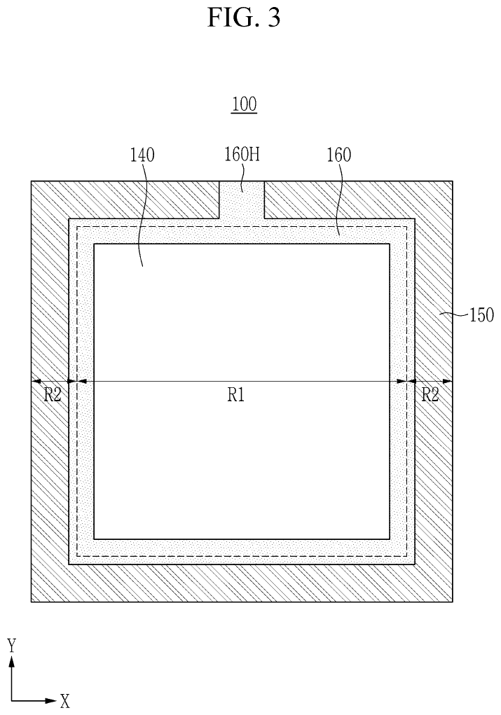

A portion of the heat generated from the semiconductor die 140 may be transferred to the dam structure 150 through the heat dissipation structure 180. Since exterior sides of the dam structure 150 are exposed to the outside, the dam structure 150 may dissipate a portion of a heat transferred from the heat dissipation structure 180 in a lateral direction (X direction, −X direction, Y direction, or −Y direction; see FIG. 3) of the semiconductor package 100. In addition, the dam structure 150 may dissipate a portion of the heat accumulated within the semiconductor package 100 in the lateral direction (X direction, −X direction, Y direction, or −Y direction) of the semiconductor package 100. In addition, the dam structure 150 may transfer a portion of the heat transferred from the heat dissipation structure 180 to the dummy pattern structures 130.

The molding material 160 may be disposed on the substrate 110 and below a side wall portion 180S of the heat dissipation structure 180. The molding material 160 may be disposed on an interior side of the dam structure 150. The molding material 160 may cover or be on at least a portion of side surfaces of the semiconductor die 140, the connection pads 141, the third connection members 142, and the bonding pads 127.

The adhesive member 170 may be disposed between the semiconductor die 140 and the heat dissipation structure 180, between the dam structure 150 and the heat dissipation structure 180, and between the molding material 160 and the heat dissipation structure 180. The adhesive member 170 may attach the heat dissipation structure 180 to the semiconductor die 140, and to the dam structure 150. In some embodiments, the adhesive member 170 may include a heat or thermal interface material (TIM). A thermal interface material (TIM) may be inserted between the semiconductor die 140 generating heat and the heat dissipation structure 180 dissipating heat, thereby improving thermal coupling between the semiconductor die 140 and the heat dissipation structure 180. The thermal interface material (TIM) may fill an air layer of contact surface between the semiconductor die 140 and the heat dissipation structure 180, thereby reducing thermal contact resistance.

The heat dissipation structure 180 may be disposed on the semiconductor die 140, on the dam structure 150, and on the molding material 160. The heat dissipation structure 180 may be thermally connected to the semiconductor die 140, and to the dam structure 150. In some embodiments, the heat dissipation structure 180 may include a heat slug, a heat sink, or a heat spreader. The heat dissipation structure 180 may be divided into the side wall portion 180S and an upper plate portion or upper wall portion 180U based on a dotted line L. The side wall portion 180S and the upper plate portion 180U may define the cavity of the heat dissipation structure 180. The semiconductor die 140 may be disposed within the cavity of the heat dissipation structure 180. A lower surface of the side wall portion 180S may be adhered to the upper surface of the dam structure 150 and the molding material 160 by the adhesive member 170. An inner side surface of the side wall portion 180S may be adhered to at least a portion of the side surfaces of the semiconductor die 140 by the adhesive member 170. A lower surface of the upper plate portion 180U may be adhered to the upper surface of the semiconductor die 140 by the adhesive member 170. In some embodiments, the heat dissipation structure 180 may include a conductive material having a high thermal conductivity such as copper or aluminum.

A portion of the heat generated from the semiconductor die 140 may be transferred to the heat dissipation structure 180. Since the upper surface and exterior sides of the heat dissipation structure 180 are exposed to the outside, the heat dissipation structure 180 may dissipate a portion of a heat transferred from the semiconductor die 140 in an upward direction (Z direction) and the lateral direction (X direction, −X direction, Y direction, or −Y direction) of the semiconductor package 100. In addition, the heat dissipation structure 180 may dissipate a portion of the heat accumulated within the semiconductor package 100 in the upward direction (Z direction) and the lateral direction (X direction, −X direction, Y direction, or −Y direction) of the semiconductor package 100. In addition, the heat dissipation structure 180 may transfer a portion of the transferred heat to the dam structure 150.

According to the present disclosure, the heat generated from the semiconductor die 140 and the heat accumulated within the semiconductor package 100 may be dissipated in 6 directions of the upward direction (Z direction), the lateral direction (X direction, −X direction, Y direction, or −Y direction), and the downward direction (−Z direction) of the semiconductor package 100, such that the heat dissipation area may be maximally secured, and thermal characteristics of the semiconductor package 100 may be improved.

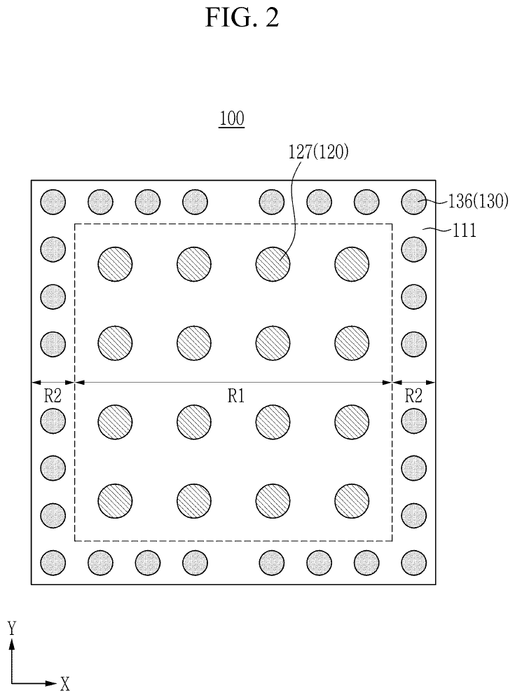

FIG. 2 is a top plan view showing the upper surface of the substrate 110 of FIG. 1.

Referring to FIG. 2, the substrate 110 may include the substrate base 111. The substrate base 111 may include the central region (first region) R1 and the edge region (second region) R2 around or surrounding the central region R1 defined by dividing the plane of the substrate base 111. A boundary of the central region R1 and the edge region R2 is shown in a dotted line. The bonding pads 127 may be disposed in the central region R1 of the upper surface of the substrate base 111. An upper surface of the third dummy via 136 may be exposed in the edge region R2 of the upper surface of the substrate base 111.

FIG. 3 is a top plan view showing the semiconductor package 100 of FIG. 1 excluding the adhesive member 170 and the heat dissipation structure 180.

Referring to FIG. 3, the semiconductor die 140 may be disposed on the central region R1 of the substrate base 111. The dam structure 150 may be disposed on the edge region R2 of the substrate base 111. In some embodiments, the dam structure 150 may have a rectangular or square frame shape. The dam structure 150 may have a shape conformally extended along the side surfaces of the semiconductor die 140. The dam structure 150 may be disposed to be spaced apart from the semiconductor die 140. The dam structure 150 may surround at least a portion of the side surfaces of the semiconductor die 140. The dam structure 150 may include a hole 160H for performing the molding process. The molding material 160 may be disposed between the semiconductor die 140 and the dam structure 150. Referring to FIG. 2 and FIG. 3, the footprint of the dummy pattern structures 130 may be included within the footprint of the dam structure 150. The dam structure 150 may vertically overlap the dummy pattern structures 130.

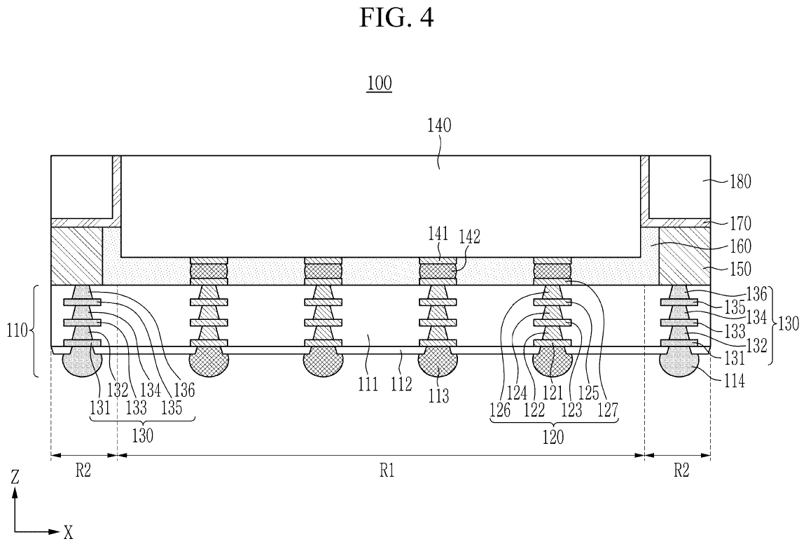

FIG. 4 is a cross-sectional view showing the semiconductor package 100 according to some embodiments.

Referring to FIG. 4, the heat dissipation structure 180 may have a rectangular frame shape including a through opening. The semiconductor die 140 may be disposed within the through opening of the heat dissipation structure 180. The upper surface of the semiconductor die 140 may be exposed from the heat dissipation structure 180 to the outside. A lower surface of the heat dissipation structure 180 may be adhered to the upper surface of the dam structure 150 and the molding material 160 by the adhesive member 170. An inner side surface of the heat dissipation structure 180 may be adhered to at least a portion of the side surfaces of the semiconductor die 140 by the adhesive member 170.

A portion of the heat generated from the semiconductor die 140 may be dissipated to the outside of the semiconductor package 100 through the upper surface of the semiconductor die 140 exposed from the heat dissipation structure 180. A portion of the heat generated from the semiconductor die 140 may be transferred to the heat dissipation structure 180. The heat dissipation structure 180 may dissipate a portion of the heat transferred from the semiconductor die 140 in the upward direction (Z direction) and the lateral direction (X direction, −X direction, Y direction, or −Y direction) of the semiconductor package 100. In addition, the heat dissipation structure 180 may dissipate a portion of the heat accumulated within the semiconductor package 100 in the upward direction (Z direction) and the lateral direction (X direction, −X direction, Y direction, or −Y direction) of the semiconductor package 100. In addition, the heat dissipation structure 180 may transfer a portion of the transferred heat to the dam structure 150.

Regarding the contents other than those described with respect to the semiconductor package 100 of FIG. 4, the contents described with respect to the semiconductor package 100 of FIG. 1 may be equally applied.

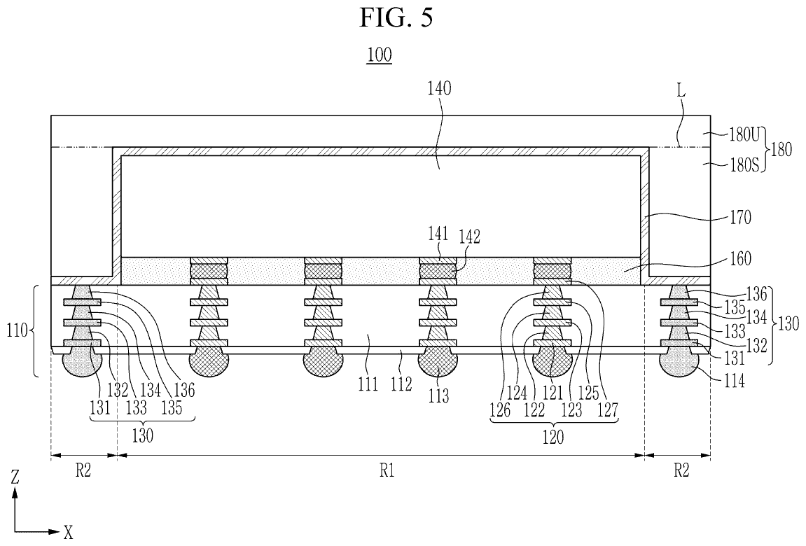

FIG. 5 is a cross-sectional view showing the semiconductor package 100 according to some embodiments.

Referring to FIG. 5, the heat dissipation structure 180 may be disposed on the substrate 110, and on the semiconductor die 140. The heat dissipation structure 180 may be disposed on the dummy pattern structures 130. The heat dissipation structure 180 may be thermally connected to the dummy pattern structures 130. The heat dissipation structure 180 may be divided into the side wall portion 180S and the upper plate portion 180U based on the dotted line L. The side wall portion 180S and the upper plate portion 180U may define the cavity of the heat dissipation structure 180. The semiconductor die 140 may be disposed within the cavity of the heat dissipation structure 180. The lower surface of the side wall portion 180S may be adhered to the upper surface of the substrate base 111 and an upper surface of the dummy pattern structures 130 by the adhesive member 170. The inner side surface of the side wall portion 180S may be adhered to all side surfaces of the semiconductor die 140 by the adhesive member 170. The lower surface of the upper plate portion 180U may be adhered to the upper surface of the semiconductor die 140 by the adhesive member 170. The footprint of the dummy pattern structures 130 may be included within the footprint of the side wall portion 180S. The side wall portion 180S may vertically overlap the dummy pattern structures 130.

The molding material 160 may be disposed on the substrate 110 and below the semiconductor die 140. The molding material 160 may be disposed on an interior side of the heat dissipation structure 180. The molding material 160 may cover or surround side surfaces of the connection pads 141, the third connection members 142, and the bonding pads 127.

The adhesive member 170 may be disposed between the substrate 110 and the heat dissipation structure 180, between the semiconductor die 140 and the heat dissipation structure 180, and between the molding material 160 and the heat dissipation structure 180. The adhesive member 170 may attach the heat dissipation structure 180 to the substrate 110, and to the semiconductor die 140.

A portion of the heat generated from the semiconductor die 140 may be transferred to the heat dissipation structure 180. Since the upper surface and exterior sides of the heat dissipation structure 180 are exposed to the outside, the heat dissipation structure 180 may dissipate a portion of the heat transferred from the semiconductor die 140 in the upward direction (Z direction) and the lateral direction (X direction, −X direction, Y direction, or −Y direction) of the semiconductor package 100. In addition, the heat dissipation structure 180 may dissipate a portion of the heat accumulated within the semiconductor package 100 in the upward direction (Z direction) and the lateral direction (X direction, −X direction, Y direction, or −Y direction) of the semiconductor package 100. In addition, the heat dissipation structure 180 may transfer a portion of the transferred heat to the dummy pattern structures 130.

Regarding the contents other than those described with respect to the semiconductor package 100 of FIG. 5, the contents described with respect to the semiconductor package 100 of FIG. 1 may be equally applied.

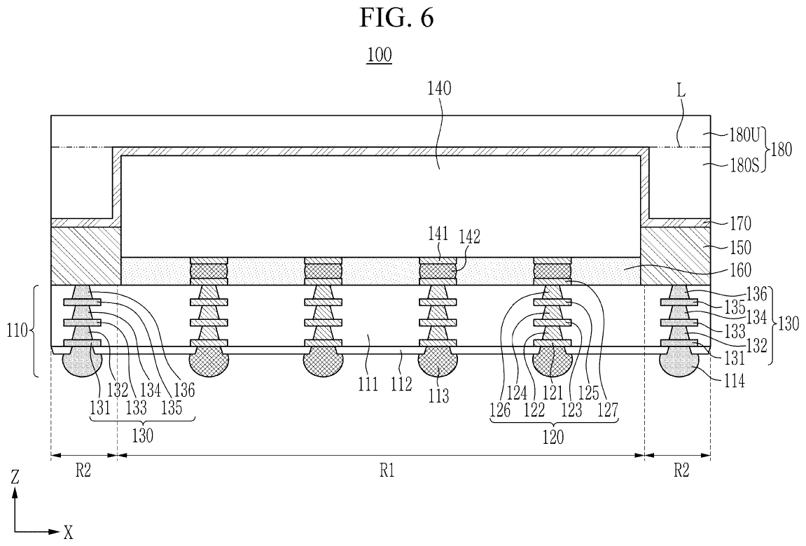

FIG. 6 is a cross-sectional view showing the semiconductor package 100 according to some embodiments.

Referring to FIG. 6, the dam structure 150 may contact the semiconductor die 140. The inner side surface of the dam structure 150 may contact the semiconductor die 140 and the molding material 160, and the exterior side of the dam structure 150 may be exposed to the outside.

The molding material 160 may be disposed on the substrate 110 and below the semiconductor die 140. The molding material 160 may be disposed on an interior side of the dam structure 150. The molding material 160 may cover or surround side surfaces of the connection pads 141, the third connection members 142, and the bonding pads 127.

The adhesive member 170 may be disposed between the semiconductor die 140 and the heat dissipation structure 180, and between the dam structure 150 and the heat dissipation structure 180.

The heat dissipation structure 180 may be disposed on the dam structure 150, and on the semiconductor die 140. The heat dissipation structure 180 may be divided into the side wall portion 180S and the upper plate portion 180U based on the dotted line L. The side wall portion 180S and the upper plate portion 180U may define the cavity of the heat dissipation structure 180. The semiconductor die 140 may be disposed within the cavity of the heat dissipation structure 180. The lower surface of the side wall portion 180S may be adhered to the upper surface of the dam structure 150 by the adhesive member 170. The inner side surface of the side wall portion 180S may be adhered to at least a portion of the side surfaces of the semiconductor die 140 by the adhesive member 170. The lower surface of the upper plate portion 180U may be adhered to the upper surface of the semiconductor die 140 by the adhesive member 170.

A portion of the heat generated from the semiconductor die 140 may be transferred to the dam structure 150 and the heat dissipation structure 180. Since the exterior sides of the dam structure 150 are exposed to the outside and the upper surface and exterior sides of the heat dissipation structure 180 are exposed to the outside, the dam structure 150 may dissipate a portion of the heat transferred from the semiconductor die 140 in the lateral direction (X direction, −X direction, Y direction, or −Y direction) of the semiconductor package 100, and the heat dissipation structure 180 may dissipate a portion of the heat transferred from the semiconductor die 140 in the upward direction (Z direction) and the lateral direction (X direction, −X direction, Y direction, or −Y direction) of the semiconductor package 100. In addition, the dam structure 150 may dissipate a portion of the heat accumulated within the semiconductor package 100 in the lateral direction (X direction, −X direction, Y direction, or −Y direction) of the semiconductor package 100, and the heat dissipation structure 180 may dissipate a portion of the heat accumulated within the semiconductor package 100 in the upward direction (Z direction) and the lateral direction (X direction, −X direction, Y direction, or −Y direction) of the semiconductor package 100. In addition, the dam structure 150 and the heat dissipation structure 180 may transfer a portion of the transferred heat to each other. In addition, the dam structure 150 may transfer a portion of the transferred heat to the dummy pattern structures 130.

Regarding the contents other than those described with respect to the semiconductor package 100 of FIG. 6, the contents described with respect to the semiconductor package 100 of FIG. 1 may be equally applied.

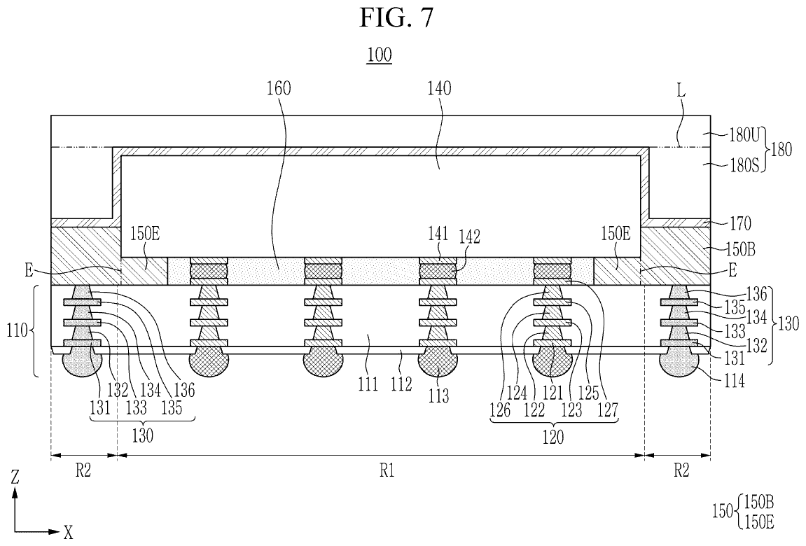

FIG. 7 is a cross-sectional view showing the semiconductor package 100 according to some embodiments.

Referring to FIG. 7, the dam structure 150 may include a main body portion 150B and an extension portion 150E. The main body portion 150B and the extension portion 150E may be divided by a line E. An inner side surface of the main body portion 150B may contact the semiconductor die 140, and an exterior side of the main body portion 150B may be exposed to the outside. The extension portion 150E may extend from the main body portion 150B in the X direction (horizontal direction) toward and facing the third connection members 142. A lower surface of the extension portion 150E may contact the substrate base 111, and may have the same (vertical) level as a (vertical) level of a lower surface of the main body portion 150B. An upper surface of the extension portion 150E may contact the lower surface of the semiconductor die 140, and may be thermally connected to the semiconductor die 140. An inner side surface of the extension portion 150E may contact the molding material 160. In some other embodiments, an upper surface of the main body portion 150B may have the same (vertical) level as a (vertical) level of the upper surface of the extension portion 150E.

The molding material 160 may be disposed on the substrate 110 and below the semiconductor die 140. The molding material 160 may be disposed on an interior side of the dam structure 150. The molding material 160 may cover or surround side surfaces of the connection pads 141, the third connection members 142, and the bonding pads 127.

The adhesive member 170 may be disposed between the semiconductor die 140 and the heat dissipation structure 180, and between the dam structure 150 and the heat dissipation structure 180.

The heat dissipation structure 180 may be disposed on the dam structure 150, and on the semiconductor die 140. The heat dissipation structure 180 may be divided into the side wall portion 180S and the upper plate portion 180U based on the dotted line L. The side wall portion 180S and the upper plate portion 180U may define the cavity of the heat dissipation structure 180. The semiconductor die 140 may be disposed within the cavity of the heat dissipation structure 180. The lower surface of the side wall portion 180S may be adhered to the upper surface of the dam structure 150 by the adhesive member 170. The inner side surface of the side wall portion 180S may be adhered to at least a portion of the side surfaces of the semiconductor die 140 by the adhesive member 170. The lower surface of the upper plate portion 180U may be adhered to the upper surface of the semiconductor die 140 by the adhesive member 170.

A portion of the heat generated from the semiconductor die 140 may be transferred to the dam structure 150 and the heat dissipation structure 180. Since the exterior sides of the dam structure 150 are exposed to the outside and the upper surface and exterior sides of the heat dissipation structure 180 are exposed to the outside, the dam structure 150 may dissipate a portion of the heat transferred from the semiconductor die 140 in the lateral direction (X direction, −X direction, Y direction, or −Y direction) of the semiconductor package 100, and the heat dissipation structure 180 may dissipate a portion of the heat transferred from the semiconductor die 140 in the upward direction (Z direction) and the lateral direction (X direction, −X direction, Y direction, or −Y direction) of the semiconductor package 100. In addition, the dam structure 150 may dissipate a portion of the heat accumulated within the semiconductor package 100 in the lateral direction (X direction, −X direction, Y direction, or −Y direction) of the semiconductor package 100, and the heat dissipation structure 180 may dissipate a portion of the heat accumulated within the semiconductor package 100 in the upward direction (Z direction) and the lateral direction (X direction, −X direction, Y direction, or −Y direction) of the semiconductor package 100. In addition, the dam structure 150 and the heat dissipation structure 180 may transfer a portion of the transferred heat to each other. In addition, the dam structure 150 may transfer a portion of the transferred heat to the dummy pattern structures 130.

Since the semiconductor die 140 has its upper surface, side surfaces, lower surface to contact the dam structure 150 and the heat dissipation structure 180, the contact areas between the dam structure 150 and the semiconductor die 140 and between the heat dissipation structure 180 and the semiconductor die 140, through which the heat generated from the semiconductor die 140 may be dissipated, may be maximized, and accordingly, thermal characteristics of the semiconductor die 140 may be improved.

Regarding the contents other than those described with respect to the semiconductor package 100 of FIG. 7, the contents described with respect to the semiconductor package 100 of FIG. 1 may be equally applied.

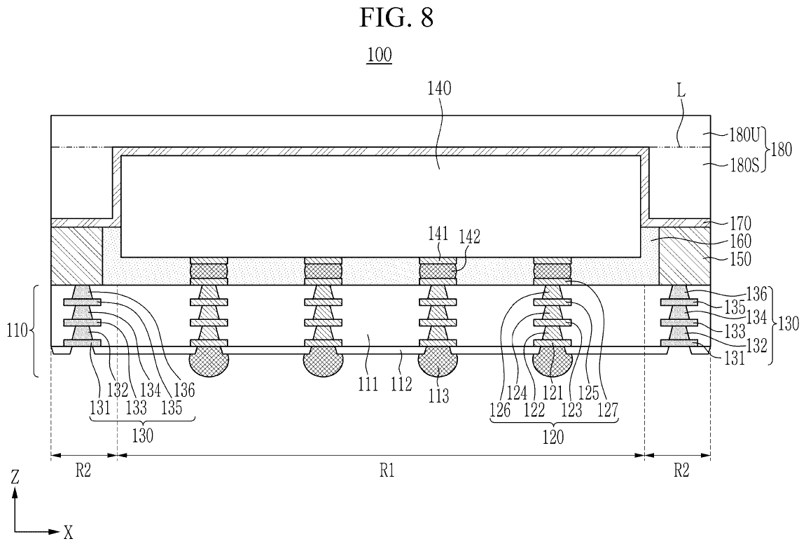

FIG. 8 is a cross-sectional view showing the semiconductor package 100 according to some embodiments.

Referring to FIG. 8, a connection member may not be connected below the dummy pattern structures 130. Since the dummy pattern structures 130 does not route signals or electric power and provides the function of dissipating heat, a connection member may not be formed below the dummy pattern structures 130. The first dummy lines 131 may be exposed to the outside.

A portion of the heat generated from the semiconductor die 140 may be transferred to the dummy pattern structures 130 through the heat dissipation structure 180 and the dam structure 150. Each of the dummy pattern structures 130 may dissipate the transferred heat in the downward direction (−Z direction) of the semiconductor package 100 through the first dummy line 131 exposed to the outside. In addition, each of the dummy pattern structures 130 may dissipate the heat accumulated within the semiconductor package 100 in the downward direction (−Z direction) of the semiconductor package 100 through the first dummy line 131 exposed to the outside.

Regarding the contents other than those described with respect to the semiconductor package 100 of FIG. 8, the contents described with respect to the semiconductor package 100 of FIG. 1 may be equally applied.

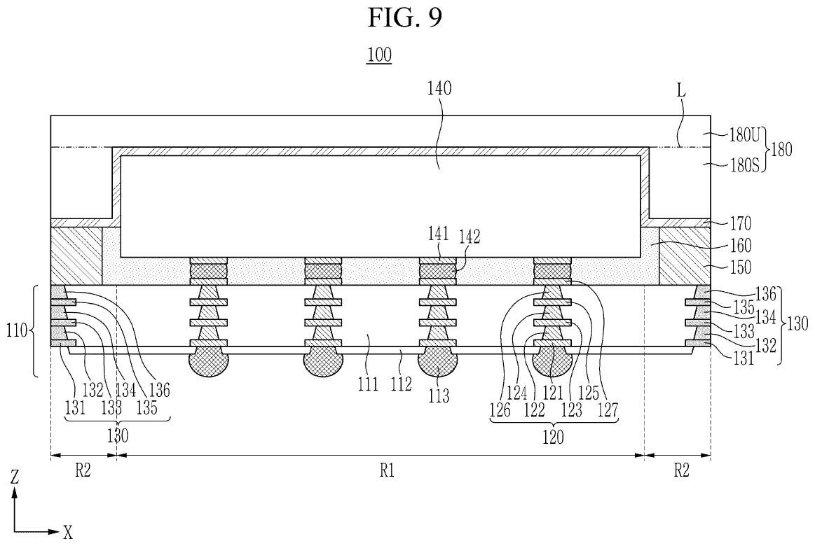

FIG. 9 is a cross-sectional view showing the semiconductor package 100 according to some embodiments.

Referring to FIG. 9, the (outer) side surface of each of the dummy pattern structures 130 may be exposed to the outside, and a connection member may not be connected below the dummy pattern structures 130. Side surfaces (e.g., outer side surfaces) of the first dummy line 131, the first dummy via 132, the second dummy line 133, the second dummy via 134, the third dummy line 135, and the third dummy via 136 of each of the dummy pattern structures 130 may be exposed from the substrate base 111 to the outside. Since the dummy pattern structures 130 does not route signals or electric power and provides the function of dissipating heat, a connection member may not be formed below the dummy pattern structures 130. Lower surfaces of the first dummy line 131 may be exposed to the outside.

A portion of the heat generated from the semiconductor die 140 may be transferred to the dummy pattern structures 130 through the heat dissipation structure 180 and the dam structure 150. Each of the dummy pattern structures 130 may dissipate the transferred heat in the downward direction (−Z direction) of the semiconductor package 100 through the first dummy line 131 exposed to the outside, and may dissipate the transferred heat in the lateral direction (X direction, −X direction, Y direction, or −Y direction) of the semiconductor package 100 through the side surface of each of the dummy pattern structures 130 exposed to the outside. In addition, each of the dummy pattern structures 130 may dissipate the heat accumulated within the semiconductor package 100 in the downward direction (−Z direction) of the semiconductor package 100 through the first dummy line 131 exposed to the outside, and may dissipate the heat accumulated within the semiconductor package 100 in the lateral direction (X direction, −X direction, Y direction, or −Y direction) of the semiconductor package 100 through the side surface of each of the dummy pattern structures 130 exposed to the outside.

Regarding the contents other than those described with respect to the semiconductor package 100 of FIG. 9, the contents described with respect to the semiconductor package 100 of FIG. 1 may be equally applied.

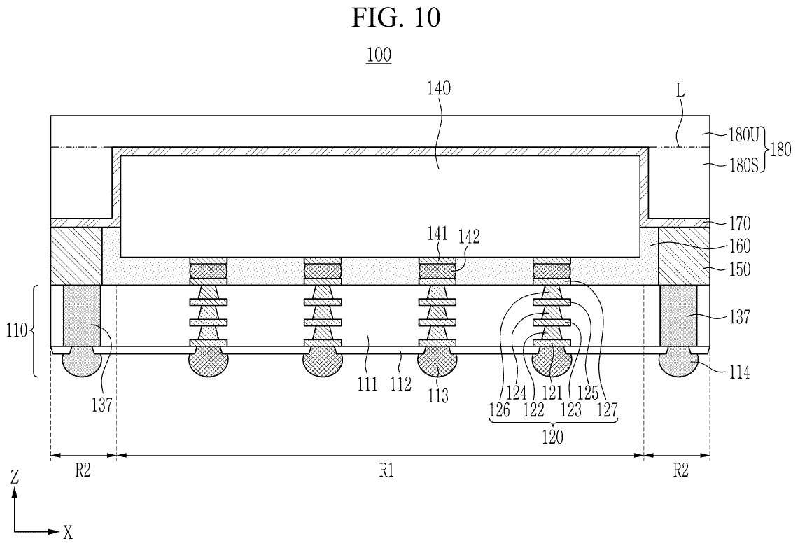

FIG. 10 is a cross-sectional view showing the semiconductor package 100 according to some embodiments.

Referring to FIG. 10, each of dummy pattern structures 137 (corresponding to 130 of FIG. 1) may be a conductive post penetrating the substrate base 111 in the Z direction (vertical direction). The conductive post may not be formed in the process of manufacturing respective one of the first wiring line 121, the first wiring via 122, the second wiring line 123, the second wiring via 124, the third wiring line 125, and the third wiring via 126 of the wiring pattern structures 120, but may be formed by performing a separate process. In some embodiments, the conductive post may include at least one of copper, aluminum, silver, tin, gold, nickel, lead, titanium, and an alloy thereof.

A portion of the heat generated from the semiconductor die 140 may be transferred to conductive posts through the heat dissipation structure 180 and the dam structure 150. The conductive posts may dissipate the transferred heat in the downward direction (−Z direction) of the semiconductor package 100 through the second connection members 114. In addition, the conductive posts may dissipate a portion of the heat accumulated within the semiconductor package 100 in the downward direction (−Z direction) of the semiconductor package 100 through the second connection members 114.

Regarding the contents other than those described with respect to the semiconductor package 100 of FIG. 10, the contents described with respect to the semiconductor package 100 of FIG. 1 may be equally applied.

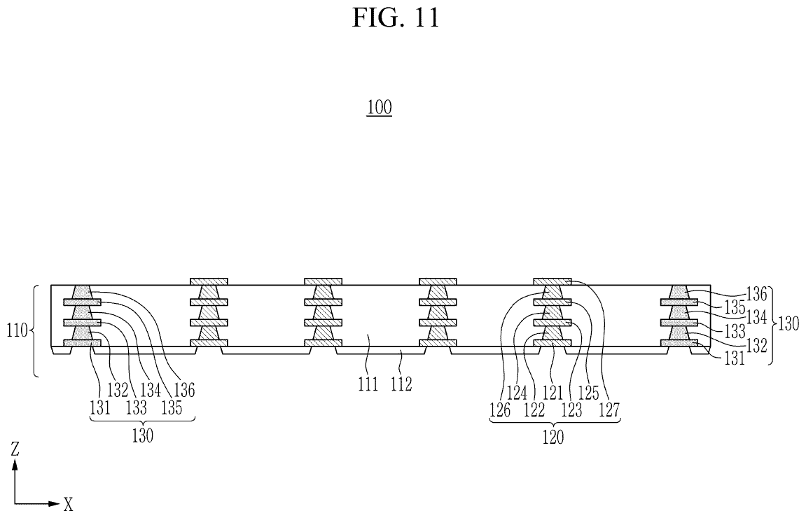

FIG. 11 to FIG. 16 are cross-sectional views for explaining a method of manufacturing the semiconductor package 100 of FIG. 1. The contents described with respect to FIG. 11 to FIG. 16 may be equally applied to a method of manufacturing the semiconductor package 100 of FIG. 3 to FIG. 10.

FIG. 11 is a cross-sectional view showing the step of providing the substrate 110.

Referring to FIG. 11, the substrate 110 in which the wiring pattern structures 120 and the dummy pattern structures 130 are formed within the substrate base 111 may be provided.

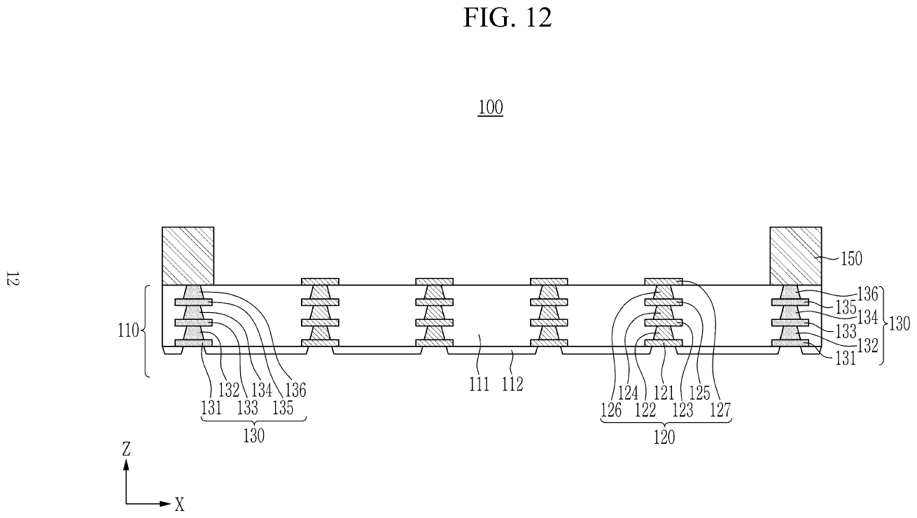

FIG. 12 is a cross-sectional view showing the step of forming the dam structure 150 on the substrate 110.

Referring to FIG. 12, the dam structure 150 may be formed on the substrate 110. The dam structure 150 may be formed by sequentially performing processes of exposure, development, and forming a conductive material, after forming the photoresist, and depending on the size of the dam structure 150, the dam structure 150 may be manufactured by repeating the above-described processes. In some embodiments, in the process of forming the conductive material, sputtering may be performed. In some embodiments, in the processes of forming the conductive material, the electroplating process may be performed after the processes of forming a seed metal layer. In some embodiments, the dam structure 150 may include copper. In some embodiments, the dam structure 150 may include a conductive material enabling electroplating.

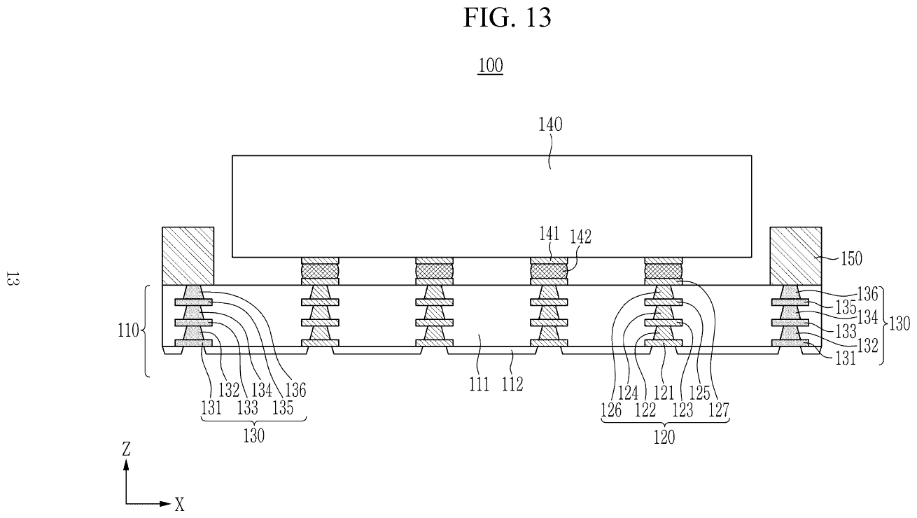

FIG. 13 is a cross-sectional view showing the step of mounting the semiconductor die 140 on the substrate 110.

Referring to FIG. 13, the semiconductor die 140 may be mounted on the substrate 110. In some embodiments, the semiconductor die 140 may be bonded on the substrate 110 by performing a flip chip bonding process. The semiconductor die 140 may be bonded to the bonding pads 127 of the substrate 110 by the third connection members 142, and accordingly, the semiconductor die 140 and the substrate 110 may be electrically interconnected.

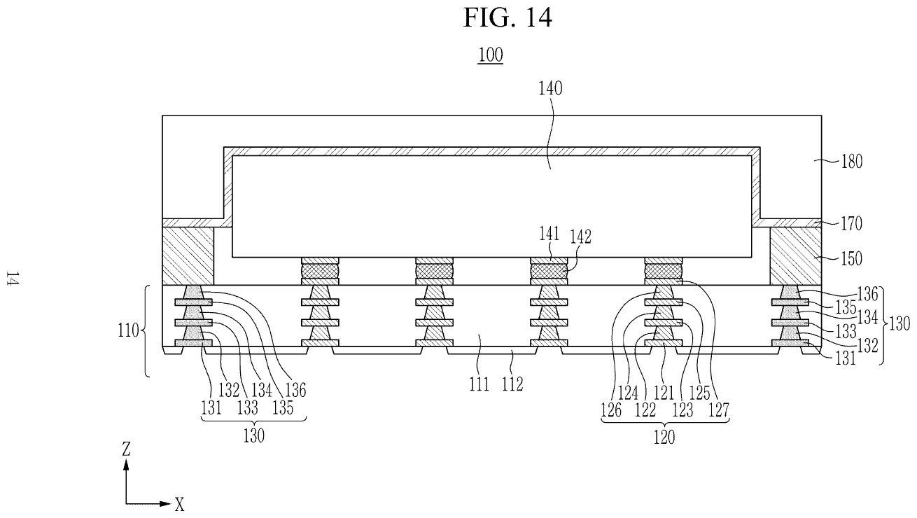

FIG. 14 is a cross-sectional view showing the step of attaching the heat dissipation structure 180 on the semiconductor die 140, and on the dam structure 150.

Referring to FIG. 14, the heat dissipation structure 180 may be attached on the semiconductor die 140, and on the dam structure 150. The heat dissipation structure 180 may be attached to the semiconductor die 140 and to the dam structure 150 by the adhesive member 170. In some embodiments, the adhesive member 170 may include a heat or thermal interface material (TIM). In some embodiments, the thermal interface material (TIM) may include thermal paste, thermal pad, phase change material (PCM) or metal material. In some embodiments, the thermal interface material (TIM) may include grease.

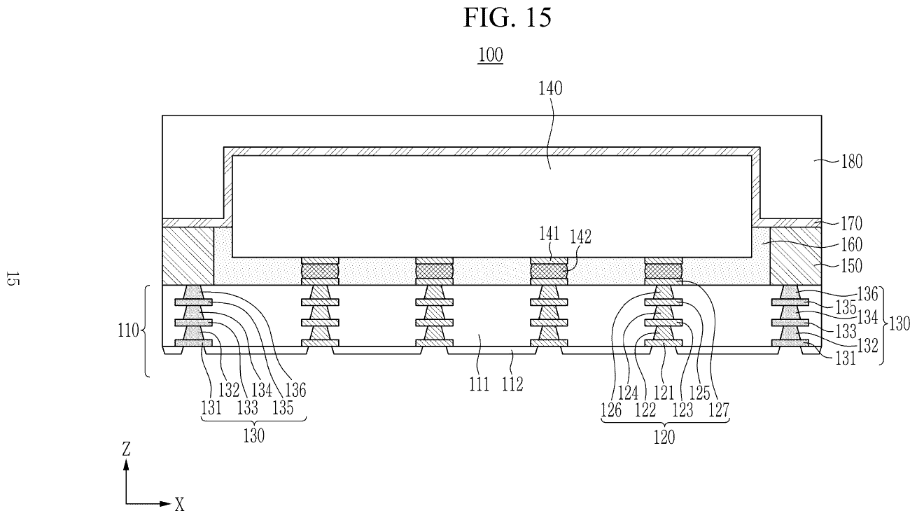

FIG. 15 is a cross-sectional view showing the step of molding the connection pads 141, the third connection members 142, and the bonding pads 127, on the substrate 110, below the semiconductor die 140, and within the dam structure 150.

Referring to FIG. 15, on the substrate 110, below the semiconductor die 140, and within the dam structure 150, the connection pads 141, the third connection members 142, and the bonding pads 127 may be molded by the molding material 160. In some embodiments, the molding process may be performed by a transfer molding process. In some embodiments, the molding material 160 may include an epoxy molding compound (EMC).

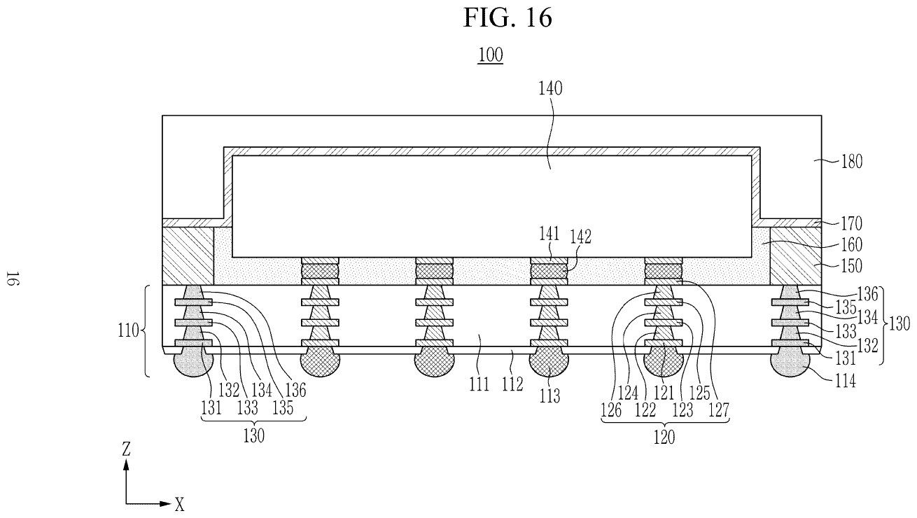

FIG. 16 is a cross-sectional view showing the step of forming the first connection members 113 and the second connection members 114 below the substrate base 111.

Referring to FIG. 16, the first connection members 113 and the second connection members 114 may be formed below the substrate base 111. In some embodiments, the first connection members 113 and the second connection members 114 may include a bump or solder ball, respectively. In some embodiments, the first connection members 113 and the second connection members 114 may include at least one of tin, silver, lead, nickel, copper, and an alloy thereof, respectively. In some other embodiments, the semiconductor package 100 including a smaller or larger number of connection members may be included in the scope of the present disclosure.

While the present disclosure has been described in connection with what is presently considered to be practical embodiments, it is to be understood that the present disclosure is not limited to the disclosed example embodiments, but, on the contrary, is intended to cover various modifications and equivalent arrangements included within the spirit and scope of the appended claims.

What is claimed is:

1. A semiconductor package, comprising:
a substrate comprising a substrate base and a plurality of dummy pattern structures penetrating the substrate base in a vertical direction;
a semiconductor die on the substrate; and
a heat dissipation structure on the substrate and surrounding at least a portion of the semiconductor die, wherein the heat dissipation structure is connected to the plurality of dummy pattern structures.

2. The semiconductor package of claim 1, wherein:
the substrate base comprises a central region and an edge region surrounding the central region; and
the plurality of dummy pattern structures are on the edge region.

3. The semiconductor package of claim 1, wherein the plurality of dummy pattern structures include outer side surfaces that are exposed to the outside.

4. The semiconductor package of claim 1, wherein:
the heat dissipation structure comprises an upper plate portion and a side wall portion;
the heat dissipation structure comprises a cavity defined by the upper plate portion and the side wall portion; and
the semiconductor die is within the cavity.

5. The semiconductor package of claim 1, wherein an upper surface of the semiconductor die is exposed to the outside.

6. The semiconductor package of claim 1, wherein the heat dissipation structure comprises a heat slug.

7. The semiconductor package of claim 1, wherein each of the plurality of dummy pattern structures comprises a dummy via stack or a conductive post.

8. The semiconductor package of claim 1, further comprising a thermal interface material (TIM) between the semiconductor die and the heat dissipation structure.

9. A semiconductor package, comprising:
a substrate comprising a substrate base and a plurality of dummy pattern structures penetrating the substrate base in a vertical direction;
a semiconductor die on the substrate;
a dam structure on the substrate and surrounding at least a portion of the semiconductor die, wherein the dam structure is connected to the plurality of dummy pattern structures; and
a heat dissipation structure on the dam structure and surrounding at least a portion of the semiconductor die, wherein the heat dissipation structure is connected to the dam structure.

10. The semiconductor package of claim 9, wherein the semiconductor die, the heat dissipation structure, the dam structure, and the plurality of dummy pattern structures are thermally connected.

11. The semiconductor package of claim 9, wherein the dam structure is spaced apart from the semiconductor die.

12. The semiconductor package of claim 9, wherein the dam structure surrounds at least a portion of side surfaces of the semiconductor die.

13. The semiconductor package of claim 9, wherein the dam structure contacts a lower surface of the semiconductor die.

14. The semiconductor package of claim 9, wherein the dam structure comprises a conductive material.

15. The semiconductor package of claim 9, wherein the dam structure vertically overlaps the plurality of dummy pattern structures.

16. The semiconductor package of claim 9, wherein an outer side surface of the dam structure is exposed to the outside.

17. A semiconductor package, comprising:
a substrate comprising a substrate base, a plurality of dummy pattern structures penetrating the substrate base in a vertical direction, and a plurality of connection members on a lower surface of the substrate base;
a semiconductor die on the substrate;
a dam structure on the substrate and surrounding at least a portion of the semiconductor die, wherein the dam structure is connected to the plurality of dummy pattern structures;
a molding material on the substrate and within the dam structure, the molding material configured to cover a portion of the semiconductor die; and
a heat dissipation structure on the dam structure, on the molding material, and surrounding at least a portion of the semiconductor die, wherein the heat dissipation structure is connected to the dam structure.

18. The semiconductor package of claim 17, wherein:
some of the plurality of connection members are a plurality of dummy connection members; and
each of the plurality of dummy connection members is connected to each of the plurality of dummy pattern structures.

19. The semiconductor package of claim 17, wherein the plurality of dummy pattern structures are exposed to the outside from the lower surface of the substrate base.

20. The semiconductor package of claim 17, wherein a vertical level of an upper surface of the molding material is the same as a vertical level of an upper surface of the dam structure.
